(19) United States
(12) Patent Application Publication
(10) Pub. No.: US 2011/0203638 A1
(43) Pub. Date: Aug. 25, 2011

(54) CONCENTRATING LINEAR PHOTOVOLTAIC RECEIVER AND METHOD FOR MANUFACTURING SAME

(75) Inventor: Mark J. O'Neill, Keller, TX (US)

(73) Assignee: ENTECH SOLAR, INC., Fort Worth, TX (US)

(21) Appl. No.: 12/830,108

(22) Filed: Jul. 2, 2010

Related U.S. Application Data
(63) Continuation-in-part of application No. 12/776,184, filed on May 7, 2010.
(60) Provisional application No. 61/226,118, filed on Jul. 16, 2009.

(51) Int. Cl. H01L 31/052; H01L 31/0232; H01L 31/0203

(52) U.S. Cl. 136/246; 136/259

(57) ABSTRACT

A photovoltaic receiver for a concentrating photovoltaic module comprises a photovoltaic cell comprising an active area with an electrically conductive gridline; an encapsulating layer disposed substantially about a predetermined portion of the photovoltaic cell where the encapsulating layer comprises a transparent portion disposed over a predetermined portion of the photovoltaic cell active area; and a prismatic cell cover attached to the transparent portion. The prismatic cell cover is dimensioned and configured to refract focused sunlight away from the electrically conductive gridline on the solar cell. The receiver may comprise a carrier; a first thermally loaded adhesive layer disposed above the carrier; a dielectric layer disposed above the first thermally loaded adhesive layer; a second thermally loaded adhesive layer disposed above the dielectric layer; a solar cell assembly disposed above the second thermally loaded adhesive layer, further comprising a photovoltaic cell comprising an active area further comprising an electrically conductive gridline; an encapsulating layer disposed substantially about a predetermined portion of the photovoltaic cell, the encapsulating layer comprising a transparent portion disposed over a predetermined portion of the photovoltaic cell active area; and a prismatic cell cover attached to the transparent portion, the prismatic cell cover dimensioned and configured to refract focused sunlight away from the electrically conductive gridline on the solar cell.

### PRIORITY

This application is a continuation-in-part of U.S. application Ser. No. 12/776,184, filed on May 7, 2010 and also claims priority through U.S. Provisional Patent Application Nos. 61/177,498, filed on May 12, 2009; 61/178,341 filed on May 14, 2009; and 61/226,118, filed Jul. 15, 2009.

### FIELD OF THE INVENTION

The invention relates generally to solar energy collection and conversion, and specifically to solar photovoltaic concentrators. In an embodiment, the invention relates more specifically to a photovoltaic receiver assembly. In a further embodiment, the invention further comprises a method for assembly of a photovoltaic receiver assembly for use in a photovoltaic concentrator to provide solar electric power.

### BACKGROUND OF THE INVENTION

Photovoltaic cells are a well known method for producing electricity from sunlight. One method of reducing the cost of photovoltaic solar collectors is to employ low cost optical concentrators to focus sunlight onto the more expensive solar cells to produce more electricity per unit area of solar cell. Much of current solar photovoltaic concentrator technology involves use of large, cumbersome, heavy, and, because of their size and bulk, relatively expensive solar panels. Most photovoltaic concentrators use either flat Fresnel lenses and/or parabolic mirrors to focus sunlight onto silicon or multi-junction photovoltaic cells.

A better optical approach is to use Fresnel lenses, which can be arched or domed, to focus sunlight onto the photovoltaic cells, since the optical advantages of arched or domed lenses over flat Fresnel lenses or mirrors are many and are well known to those of ordinary skill in the art of photovoltaic concentrator technology. However, current solar panels using large, arched Fresnel lenses are nonetheless bulky, heavy, and require large heat sinks. If the arched lens comprises an acrylic plastic, which is the presently preferred material, these acrylic lenses are flammable and can be damaged due to exposure to weather and environmental elements such as hail, wind, blowing sand, and the like. Furthermore, acrylic lens material allows water vapor to diffuse through the lens into the interior of the concentrator panel, where condensation can cause optical (condensation on the lens) and electrical (condensation on the cell circuit) problems.

A linear photovoltaic receiver may be assembled from a plurality of cells and bypass diodes, with the resulting linear photovoltaic receiver product being applicable to linear photovoltaic concentrator modules that use linear optical concentrators to generate a focal line of light onto a photovoltaic receiver.

### DRAWINGS

FIG. 1 is a view in partial perspective of an exemplary photovoltaic concentrator panel;

FIG. 2 is a view in partial perspective cut-away of a close-up exploded view of a portion of an exemplary photovoltaic concentrator panel;

FIG. 3 is a diagrammatic view of ray trace vectors of an exemplary embodiment;

FIG. 4 is a view in partial perspective cut-away of an exemplary embodiment with Fresnel lens supports with one exemplary Fresnel lens and its support ends shown in exploded view above the container;

FIG. 5 is a view in partial perspective cut-away of an exemplary embodiment with Fresnel lens supports;

FIG. 6 is a view in partial perspective cut-away of an exemplary photovoltaic receiver assembly;

FIG. 7 is a cross-sectional schematic illustrating how a prismatic cell cover refracts focused solar rays which are incident on top of a receiver after being focused by a Fresnel lens so that the rays fall between gridlines; and

FIGS. 8a and 8b (collectively referred to as FIG. 8) are further views in partial perspective of an exemplary photovoltaic cell circuit assembly, including cells, bypass diodes, and electrically conducting interconnect ribbon (top and bottom views).

### BRIEF DESCRIPTION OF PREFERRED EMBODIMENTS

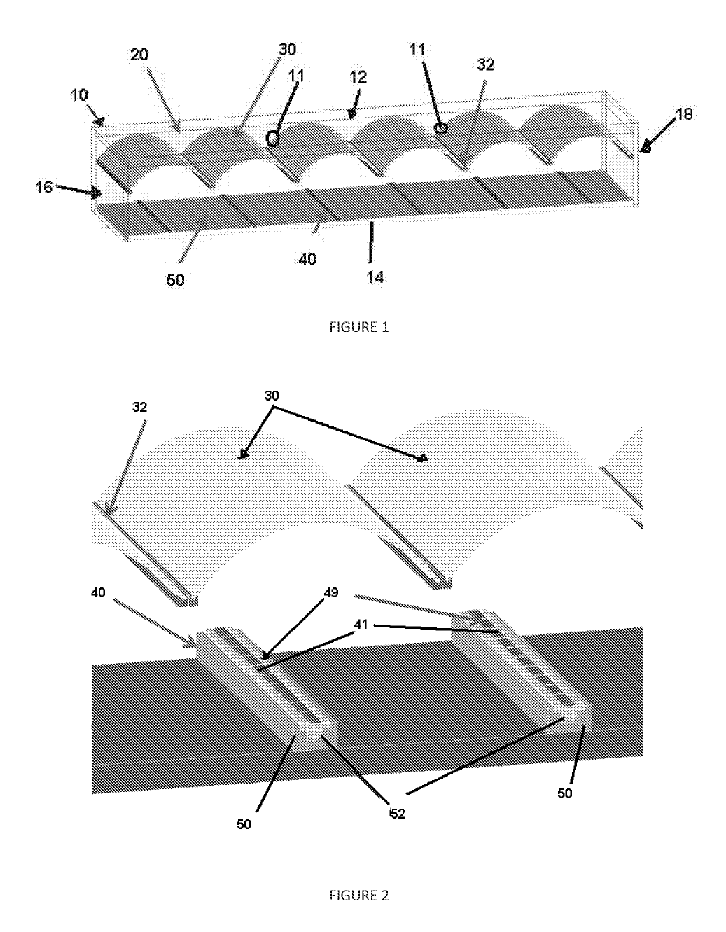

Referring now to FIG. 1, in an embodiment, photovoltaic concentrator panel 1 comprises container 10, one or more windows 20, one or more Fresnel lens concentrators 30, and one or more receivers 40. In certain embodiments, photovoltaic concentrator panel 1 further comprises one or more radiators 50.

Container 10 comprises top 12, sides 15-18, and bottom 14. Sides 15 and 17 (FIG. 4) may be (and are typically) configured as end plates attached to sides 16 and 18 and used to close out container 10. In one preferred embodiment, end plates 15 and 17, sides 16 and 18, and bottom 14 comprise a single-piece formed aluminum unit resembling a rectangular pan with an open top. Note that in FIG. 4, end plate 15 is not shown directly as FIG. 4 is a cutaway view of container 10.

In certain contemplated embodiments, bottom 14 comprises an aluminum radiator sheet. However, the container material is in no way restricted to aluminum, since many other materials such as galvanized steel, plastics, glass, or the like, or a combination thereof could be used.

As typically configured, container 10 comprises a weatherproof enclosure, with water-tight joints or seals between the exterior components, including top 12, sides 16 and 18, bottom 14, and end plates 15 and 17 (FIG. 4). Configured in this manner, container 10 is suited for allowing the mounting of electronic circuits and/or components within container 10, these electronic components typically representing balance-of-system elements as may be found in typical solar power systems. In certain embodiments, these electronic circuits and components may be mounted to one or more of the inner surfaces of container 10 and be operatively interconnected to each other and to receivers 40 to provide useful balance-of-system functionality, such as DC-to-DC voltage converters, DC-to-AC inverters, sun-tracking controllers which may comprise an open-loop microprocessor-based unit, or the like, or combinations thereof. Internal mounting of these electronic components can save cost at the system level by eliminating the need for weatherproof junction boxes for these components and by allowing factory installation of these electronic components inside container 10, rather than field assembly of these electronic components.

In certain contemplated embodiments, container 10 may also include one or more breathing ports 11, which provides a fluid conduit between the interior of container 10 and the outside environment and is dimensioned to help prevent a pressure differential between an interior portion of container 10 and the outside air.

In preferred embodiments, top 12 comprises a transparent material which defines window 20. Typically, window 20 comprises a glass with typical dimensions of around 1 meter wide by around 1.5 meters long. In currently contemplated embodiments, window 20 may comprise a glass coated with an anti-reflection (AR) coating on one or both of its surfaces, minimizing the optical transmittance loss for solar rays passing through the glass. For example, an inexpensive sol-gel coating on both glass surfaces can achieve 96% net transmittance for low-iron, tempered float glass with a thickness of around 3 mm The window material is in no way restricted to glass, since any transparent material, such as plastic sheet or film, could serve the same function. For example, in alternative, lighter weight embodiments, window 20 may comprise a polymer sheet, such as acrylic plastic, a polymer film such as ETFE or FEP fluoropolymer material, a laminated combination of glass and polymer materials, or the like, or a combination thereof.

Window 20 may be coextensive with all of top 12 or comprise a predetermined portion of top 12 such as being disposed within a glass mounting frame (not shown in the figures) that is at least coextensive with top 12.

In currently preferred embodiments, window 20 is not a lens and does not contain any lens features, serving instead to allow incident light into container 10 and to protect Fresnel lens concentrator 30, receiver 40, and other interior components from exposure to weather elements such as rain, hail, blowing sand, dirt, and wind.

End plates 15 and 17 (FIG. 4) and sides 16 and 18 can comprise any suitable material, preferably non-flammable, such as a metal or glass.

Referring additionally to FIG. 2, Fresnel lens concentrators 30 are typically acrylic or other polymeric Fresnel lens concentrators 30 which are attached to lens support such as lens carrier 32 or other lens supports such as end supports 19a and 19b (FIG. 4) such that there is typically one such Fresnel lens concentrator 30 per receiver 40. As discussed herein below, receiver 40 comprises one or more photovoltaic cell circuits 49 which are typically a linear array of a plurality of operatively interconnected photovoltaic cells 41. In a further typical embodiment, Fresnel lens concentrators 30 are arched. An important feature of Fresnel lens concentrator 30 is that it is thin, lightweight, and economical to produce. In a preferred embodiment, the lens is a flexible, arched, acrylic or other polymeric symmetrical-refraction Fresnel lens about 0.25 mm thick and made by a continuous roll-to-roll process, such as lens film embossing. Such lens film is typically made in flat form and delivered on rolls and has relatively small dimensions (e.g., around 16 cm aperture width, 14 cm focal length, and 160 cm aperture length). For use in the present invention, the lens film is typically first trimmed to final size and then mechanically bent or thermally formed into the arched shape and attached to lens carrier 32 or other lens supports such as 19a,19b. However, shapes other than arched may be used, provided they conform to the teachings herein.

Using an array of small Fresnel lens concentrators 30 allows photovoltaic concentrator panel 1 to have a depth of only a few inches versus a conventional concentrating photovoltaic module depth of 2-3 feet. This can save costs such as for enclosure materials, packaging/shipping cost, and/or installation cost.

A further important feature of Fresnel lens concentrator 30 is that it is mounted within container 10 independently of window 20. Thus, in typical installations, Fresnel lens concentrators 30 and receivers 40 are configured as independent pairs with self-aligning supports which are not connected to window 20, i.e., one Fresnel lens concentrator 30 is paired with one specific receiver 40. It is understood that there can be a plurality of paired Fresnel lens concentrators 30 and corresponding photovoltaic cell circuits 49 within container 10.

If photovoltaic concentrator panel 1 uses arched or dome lens concentrators 30 and multi junction photovoltaic cells 41, the design of dome lens concentrators 30 may further include color-mixing features as are known in the art. Container 10, including window 20 and bottom 14 which may be dimensioned and configured to act as a heat rejection structure, can be adapted to a number of different photovoltaic concentrator configurations using free-standing lens concentrators 30 of various geometries focusing onto photovoltaic cells 41 of various types. The lens concentrator material is in no way restricted to acrylic or other polymeric plastic, since lens concentrators 30 could be made of any transparent moldable material, such as clear silicone materials.

Referring additionally to FIG. 4, in typical embodiments, Fresnel lens concentrator 30 is not bonded to window 20. In currently contemplated embodiments, each Fresnel lens concentrator 30 is secured along a predetermined border into lens carrier 32, if side support is used, or along its ends, if end supports such as end supports 19a and 19b are used. If side support is used, each lens carrier 32 is supported at its ends, or incrementally along its length, to maintain its position relative to the center of photovoltaic cell circuit 49, thereby ensuring that the focal line produced by Fresnel lens concentrator 30 remains centered on photovoltaic cell circuit 49. In certain embodiments, a point-focus dome-shaped lens concentrators 30 may be used where photovoltaic cell circuit 49 is disposed in an area corresponding to a focal spot of dome lens. If end supports 19a,19b are used, the need for the lens carrier 32 is eliminated by replacing lens carriers 32 with end supports 19a and 19b. In a preferred embodiment, supporting each Fresnel lens concentrator 30 in alignment with each receiver 40 and/or its photovoltaic cell circuit 49 is made possible by separating the individual Fresnel lens concentrators 30 from window 20.

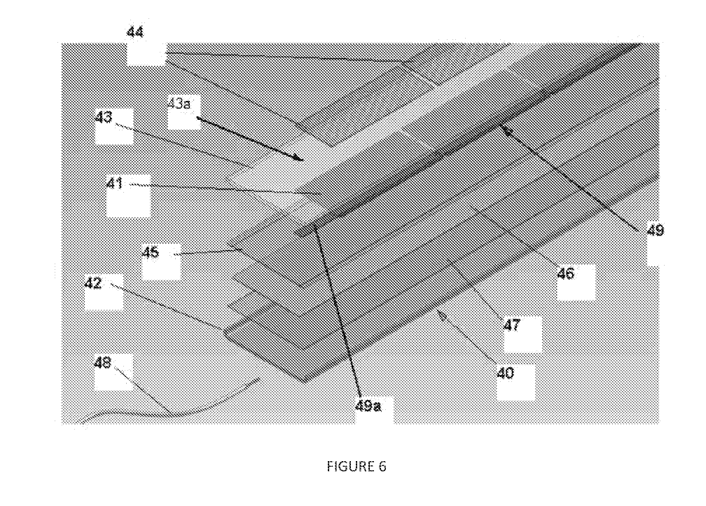

Referring additionally to FIG. 6, with respect to receiver 40, one or more photovoltaic cells 41 are assembled into photovoltaic cell circuit 49 and attached to carrier 42 (FIG. 6) which may serve as a mounting surface for photovoltaic cells 41 and may also contain layers which serve as an electrical insulator to prevent shorting of photovoltaic cells 41 to bottom 14 (FIG. 1) of photovoltaic concentrator panel 1 (FIG. 1). These photovoltaic cells 41 are typically silicon solar cells and typically around 0.8 cm wide which may be made by conventional low-cost mass-production processes widely used in the one-sun solar cell industry. The solar cell material is in no way restricted to silicon, since many other cell materials from gallium arsenide (GaAs) to copper indium gallium selenide (CIGS) to triple junction gallium indium phosphide-gallium arsenide-germanium (GaInP—GaAs—Ge) could be used.

Typically, receivers 40 are fully encapsulated and dielectrically isolated and capable of high-voltage operation for decades with no ground faults (shorts to the heat rejection structures). Carrier 42 may act as a substrate and may or may not also comprise a flex circuit or printed circuit board or other electronic circuit element, as is well known to those of ordinary skill in the art of assembling photovoltaic cell circuits or other types of electronic circuits. In one preferred embodiment, carrier 42, acting as an electrical insulator, may include one or more independent dielectric film layers 46, each made of a high-voltage insulation material such as polyimide, disposed below photovoltaic concentrator cell circuit 49. Two or more independent dielectric film layers 46 are preferred to prevent insulation breakdown due to, e.g., a pinhole or other defect in one dielectric film layer 46.

Still referring to FIG. 6, in its simplest form, in the preferred embodiment of receiver 40, receiver 40 may comprise one or more photovoltaic concentrator cell circuits 49. Each photovoltaic cell circuit 49 typically comprises one or more photovoltaic cells 41 which are electrically interconnected using electrical conduit 49a. Each electrical conduit 49a is typically a copper or other metallic strip operatively in electrical communication with a portion of photovoltaic cell 41, e.g. the top surface of one photovoltaic cell 41 and the bottom surface of a neighboring photovoltaic cell 41, thereby joining these two photovoltaic cells 41 in series electrically. In an embodiment, electrical conduit 49a comprises a solder plated copper ribbon. This pattern typically repeats along photovoltaic cell circuit 49 until photovoltaic cell circuit 49 is completed with one or more end wires 48, which may be insulated copper, exiting photovoltaic receiver 40 at each end of photovoltaic cell circuit 49. In a preferred embodiment, bypass diode chips are placed between the top and bottom metallic strips next to each cell 41, to protect the cell and bypass the circuit current in case of shading of the cell.

Carrier 42, typically a strip of aluminum, is used to support photovoltaic cell circuit 49. Photovoltaic concentrator cell circuit 49 is typically adhesively bonded to first adhesive layer 45 which may be thermally loaded. Dielectric film layer 46 may be present and disposed above first adhesive layer 45 and adhesively bonded to second adhesive layer 47 which is then bonded to carrier 42. Second adhesive layer 47 may be thermally loaded. Photovoltaic cells 41 which are electrically interconnected using electrical conduit 49a are disposed above second adhesive layer 47. Carrier 42 may be attached to bottom 14 of container 10 using any suitable means such as by a further adhesive layer.

In a preferred embodiment, the layers beneath photovoltaic cell circuit 49 comprise thermally loaded adhesive layer 45. In a preferred embodiment, thermally loaded adhesive layer 45 further comprising a silicone material such as alumina-loaded Dow Corning Sylgard® 184; dielectric film layer 46, further comprising one or more laminated layers of polyimide material such as DuPont Kapton® CR, where two such layers are preferred; and adhesive layer 47, further comprising a thermally loaded silicone such as alumina-loaded Dow Corning Sylgard® 184. The laminate may comprise Teflon® FEP. Where dielectric layer 46 comprises redundant layers of polyimide, these provide added durability and reliability in case of a defect such as an air bubble or void in one of the layers. In a preferred embodiment, the redundant layers of polyimide are bonded together and are each around 50μ thick.

For ease of handling and assembly, photovoltaic cell circuit 49 can be bonded to dielectric film layer 46 using a thermally loaded adhesive in first adhesive layer 45 and then bonded to carrier 42 using a second thermally loaded adhesive layer 47. Carrier 42 itself may be attached to bottom 14 of container 10 using another layer, e.g., a third layer, of thermally loaded adhesive.

Encapsulating layer 43 is attached to a top portion of photovoltaic cell circuit 49, and one or more prismatic cell covers 44 are attached to, molded onto, or otherwise integrated into the top surface of encapsulating layer 43 to aid in focusing incident light energy onto non-metallized, current-producing, photovoltaically active portions of photovoltaic cell circuit 49. Prismatic cell cover 44 typically comprises the same material as transparent encapsulating layer 43, For example, in a preferred embodiment, clear encapsulating layer 43 comprises silicone material, such as Dow Corning Sylgard® 184, and prismatic cell cover 44 comprises silicone material such as Dow Corning Sylgard® 184. In preferred embodiments, prismatic cell cover 44 reduces the shadowing loss of metal gridlines on the top surface of photovoltaic cells 41 by refracting focused sunlight away from these electrically conductive gridlines onto an active area of the solar cell material instead. Prismatic cell cover 44 is typically molded onto, bonded onto, or otherwise attached to clear encapsulating layer 43 over each photovoltaic cell 41 to eliminate gridline shadowing loss, such as into or onto the transparent portion of encapsulating layer 43. In some preferred embodiments, clear encapsulating layer 43 may include a transparent film to improve weather resistance, such as ETFE film or FEP Teflon film. In these embodiments, prismatic cell cover 44 may be molded onto, bonded onto, or otherwise attached to the transparent film portion of encapsulating layer 43.

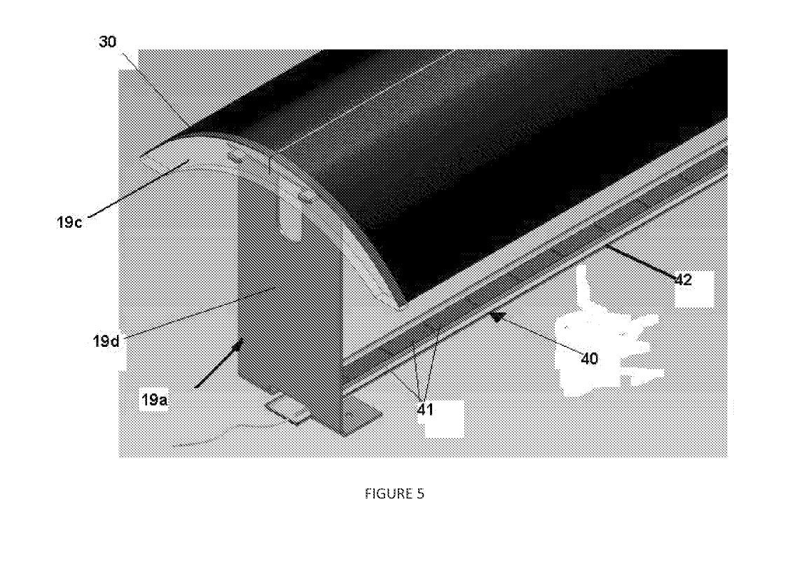

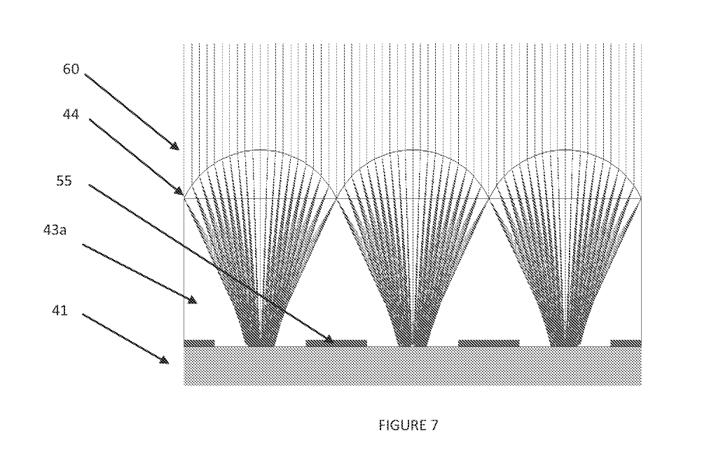

As shown in the cross-sectional schematic of FIG. 7, the prismatic cell cover 44 refracts focused solar rays 60 which are incident on top of receiver 40 (FIG. 6) after being focused by Fresnel lens 30 (FIG. 5) so that rays 60 fall between gridlines 55, Electrically conductive gridline 55 typically comprises multiple parallel gridlines 55 dimensioned and configured with a fixed spacing between these multiple parallel gridlines 55. Prismatic cell cover 44 may also comprise multiple partially cylindrically shaped optical elements comprising the same width as the spacing between gridlines 55. In this way, peaks of the partially cylindrical optical elements are located approximately around halfway between gridlines 55.

For a concentrator cell 41 to perform efficiently with the higher current densities due to concentration, such gridlines 55 need to cover a significant portion of the top surface of solar cell 41. Without the prismatic cover, many solar rays 60 would be incident on top of these opaque gridlines 55 and therefore prevented from reaching active solar cell material, thereby lowering the solar cell power output significantly. In contrast, with the prismatic cover, these rays will reach active solar cell material, thereby enhancing the cell's electrical power output, FIG. 7 shows the encapsulating layer 43a over the top surface of the solar cell 41, with prismatic cell cover 44 bonded onto or molded onto or otherwise attached to a prismatic cell cover receiving surface area, e.g. an exposed transparent portion of encapsulating layer 43a such as a top or front surface area of encapsulating layer 43a. Once prismatic cell cover 44 is in place, the exposed transparent portion of encapsulating layer 43a is no longer exposed, i.e. prismatic cell cover 44 is substantially in communication with and covers that exposed transparent portion of encapsulating layer 43a. Optically, the assembly of prismatic cell cover 44 and encapsulating layer 43a forms a substantially continuous transparent optical medium for collecting, refracting, and delivering solar rays 60 to active regions of solar cell 41 between gridlines 55.

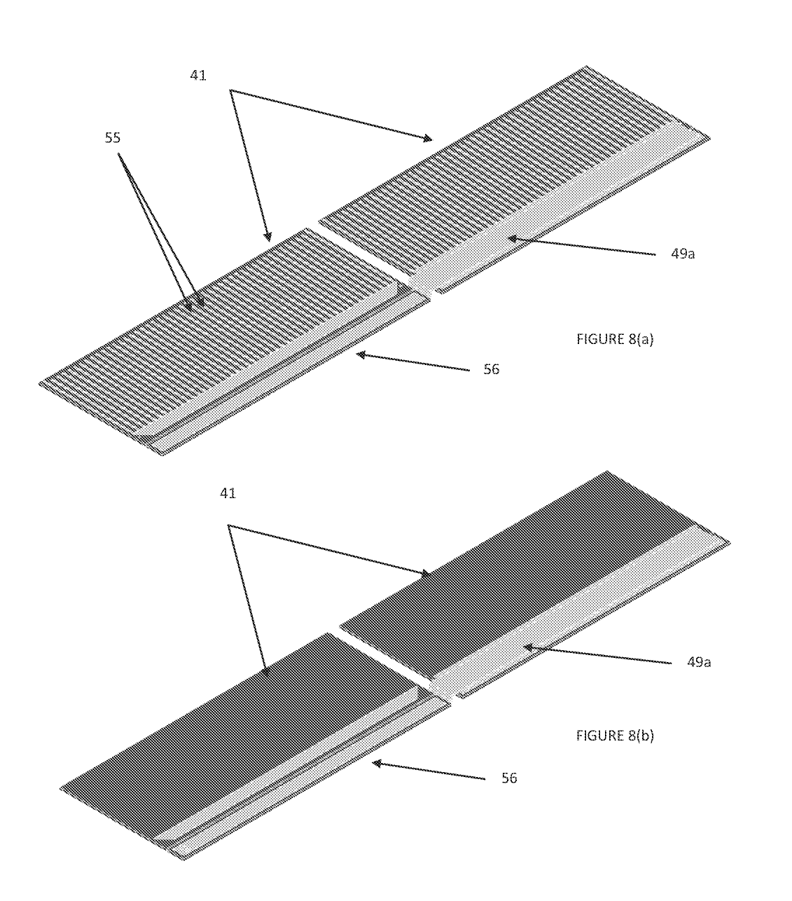

FIGS. 8a and 8b show the typical pattern of gridlines 55 on the top surface of the solar cell 41 in more detail. FIGS. 8a and 8b also show the separate semiconductor chip 56 which serves as the bypass diode for solar cell 41. The same electrical conductor 49a is used to electrically contact both the solar cell 41 and the bypass diode 56 on both the top (front) and bottom (back) surfaces of both the solar cell 41 and the diode 56. This electrical conductor 49a wraps from the top of one set of cell 41 and diode 50 to the bottom of the neighboring set of cell 41 and diode 56, placing these neighboring sets of devices in series electrically, while keeping the cell and diode in each individual set in parallel to one another electrically. The diode 56 provides a path for current to flow around cell 41 in the event that cell 41 cannot conduct the full current of the series-connected string of cells, which can occur if cell 41 is shaded or damaged in some way. Bypass diode 56 keeps cell 41 from going into reverse voltage bias and overheating in such an event.

Encapsulating layer 43 is disposed about a predetermined portion of photovoltaic cell 41 as discussed herein. This predetermined portion may be the substantially the entire area of cell 41 or the entire top surface area of the full receiver 40 as shown by encapsulating layer 43a in FIG. 6. In a preferred embodiment, encapsulating layer 43 comprises transparent portion 43a disposed over a predetermined portion of active area 41a where transparent portion 43a comprises a prismatic cell cover receiving surface area such as an exposed portion of transparent portion 43a adapted to receive prismatic cell cover 44. Prismatic cell cover 44 is attached to or otherwise integrated into the transparent portion 43a where prismatic cell cover 44 is dimensioned and configured to refract focused sunlight away from electrically conductive gridlines 55, as discussed herein and as shown in FIG. 7.

Still referring to FIG. 6 and additionally to FIG. 7 and FIGS. 8a and 8b, in certain embodiments, photovoltaic receiver 40 comprises a plurality of photovoltaic cells 41 mounted on carrier 42, with dielectric film 46 providing electrical isolation between the cells 41 and the carrier 42. In a preferred embodiment, polyimide (e.g., DuPont Kapton®) may be used as this dielectric film 46, and may be bonded to carrier 42 and solar cells 41 using thermally conductive layers 45 and 47 which may comprise an alumina-loaded silicone adhesive. As described herein, the plurality of photovoltaic cells 41 are typically electrically interconnected in series via electrical conduit 49a and may be further electrically connected to one or more bypass diodes 56 as shown in FIGS. 8a and 8b.

Referring back to FIG. 2, in another embodiment, photovoltaic cell circuit 49 is further mounted on heat sink 50 which acts as a thermal conduit as well as a support for photovoltaic cell circuit 49. In certain of these contemplated embodiments, each heat sink 50 further comprises fluid conduit 52, either of which comprises a substantially flat upper surface to which one or more photovoltaic cell circuits 49 are mounted. In a preferred one of these embodiments, fluid conduit 52 is at least partially disposed internally within heat sink 50. In these embodiments, heat sink 50 is adapted to transfer waste heat from receiver 40 into fluid within fluid carrier 52. Such fluid may be in the form of a liquid such as propylene glycol-water solution, or may be in the form of a liquid-to-vapor phase change fluid serving, for example, as a heat pipe. Additionally, the liquid may be pumped through fluid carrier 52 by use of an auxiliary pump (not shown in the figures). Adequate waste heat rejection may alternatively be via passive air-cooling, such as by using a thin aluminum back sheet radiator, e.g., 1 mm thick. It is currently contemplated that an air-cooled version of the invention will be used for electricity production alone while a liquid-cooled version will be used for combined electricity and heat production.

Waste heat may therefore be efficiently collected by insulating heat sink 50 to minimize heat losses to the environment and also by delivering the heat absorbed by the fluid to a nearby heat load, such as may be appropriate for use as hot water for an industrial or commercial application. The insulation material can also wrap around the sides and top edges of heat sink 50, leaving only the active solar cell material of receiver 40 exposed to the focus of Fresnel lens concentrator 30. If multiple heat sinks 50 are used in photovoltaic concentrator panel 1, corresponding to multiple photovoltaic cell circuits 49 under multiple Fresnel lens concentrators 30, fluid carriers 52 can be connected to insulated manifolds or other insulated fluid distribution system elements at the ends of the photovoltaic concentrator panel 1, using materials and designs well known to those of ordinary skill in the art in solar heat collection. In one embodiment, the thermal insulation material comprises an isocyanurate foam or other thermally insulating foam, materials well known to those of ordinary skill in the art of solar heat collection.

In some of these embodiments, when the waste heat generated within receiver 40 is to be dissipated to the surroundings, bottom 14 also acts as a heat exchanger and comprises a thermally conductive material, e.g., aluminum, which acts as a heat sink for receiver 40 as well as for transferring the waste heat to the surroundings such as by convection and radiation. Thus, in these embodiments bottom 14 may act as a backplane radiator for ambient air-cooling. To minimize the radiator temperature for the air-cooling approach, the surfaces of the backplane radiator should be reflective of solar wavelengths and absorptive/emissive of infrared wavelengths, which can be achieved with clear anodizing of aluminum or with white paint.

In another preferred embodiment of these embodiments, when the waste heat generated within receiver 40 is to be collected and used, bottom 14 comprises a low-cost, durable enclosure bottom made of a material such as glass or a suitable metal which may also act as a support for a thermally insulated, liquid-cooled receiver 40. A glass back material has an additional advantage of allowing diffuse sunlight to be transmitted completely through top 12 and bottom 14 of photovoltaic concentrator panel 1, reducing both the temperature of Fresnel lens concentrators 30 inside photovoltaic concentrator panel 1 and the external surfaces of photovoltaic concentrator panel 1.

Moreover, the configuration and relatively small size of receiver 40 is amenable to use of high-quality, proven solar cell and semiconductor circuit assembly fabrication equipment and methods and can be fully automated, producing assemblies at a higher-speed and lower cost and better quality.

Small receiver 40 or photovoltaic cell circuit 49 assemblies are more efficient than large receiver 40 or photovoltaic cell circuit 49 assemblies, due to the smaller currents and the smaller distances that the currents must be conducted, making the disclosed receivers 40 more efficient than receivers 40 in conventional larger concentrating photovoltaic modules. Further, small apertures make waste heat rejection simpler and less costly, due to the small quantity of waste heat and the small distances this waste heat needs to be conducted for dissipation, resulting in lower cell temperatures and higher cell efficiencies than for conventional larger concentrating photovoltaic modules

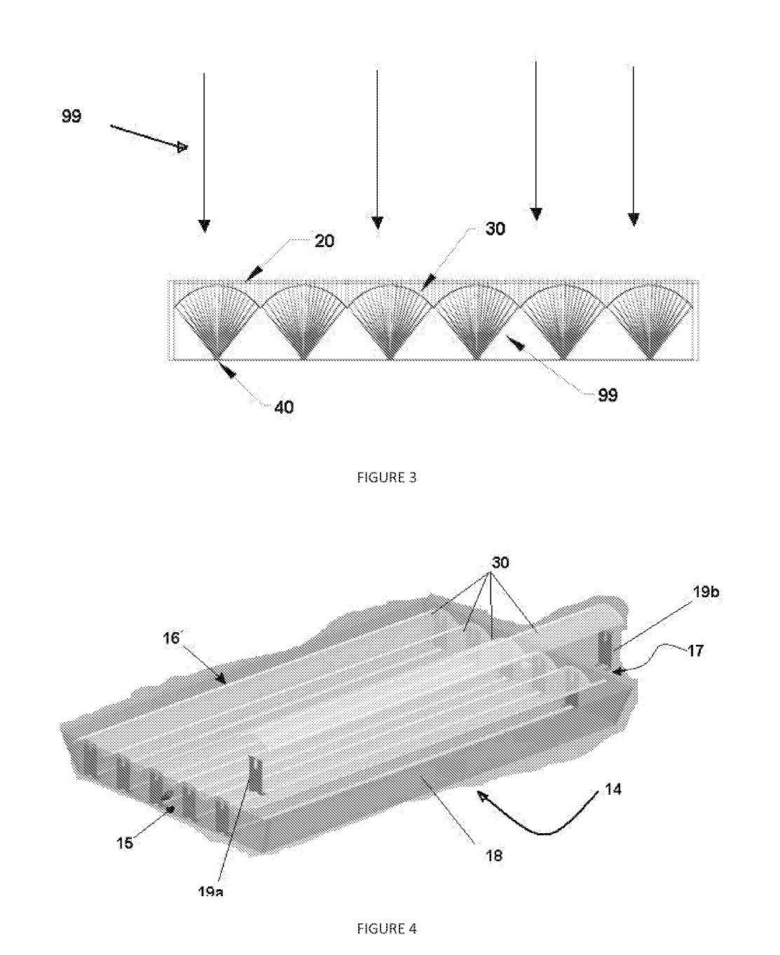

Referring now to FIG. 3, as further clarification of photovoltaic concentrator panel 1 functionality, the ray trace diagram in FIG. 3 illustrates the path of solar rays 99, first through window 20, then focused by Fresnel lens concentrators 30, and finally absorbed and converted into useful energy by photovoltaic cell circuits 49 in receivers 40 (FIG. 2).

Referring now to FIGS. 4-5, as further clarification of the construction of one preferred embodiment of photovoltaic concentrator panel 1, each Fresnel lens concentrator 30 is supported by one or more end arches 19a,19b which are attached to bottom 14. In a preferred embodiment, the attachment is via simple metal springs, e.g. 19d, which apply a slight tension force to Fresnel lens concentrator 30 to keep it substantially straight and in proper position by applying an outward force to upper arch attachment 19c which is bonded to lens 30, thereby applying a lengthwise tensioning force to lens 30.

Referring now to FIG. 5, as further clarification of the details in certain embodiments for each end arch 19a and its relationship with photovoltaic cell circuit 49 in receiver 40, where photovoltaic cell circuit 49 is aligned to the focal line of arched Fresnel lens concentrator 30, one preferred embodiment is shown whereby carrier 42 serves to support receiver 40 and is configured to self-align with a feature of end arch 19a. Such self-alignment of an individual Fresnel lens concentrator 30 with its paired photovoltaic cell circuit 49 is only possible when Fresnel lens concentrator 30 is not attached to window 20 (FIG. 1).

In the operation of a preferred method of assembly, a photovoltaic cell circuit, e.g., a plurality of photovoltaic cells 41 electrically interconnected via electrical conduit 49a, is completely encapsulated for electrical isolation and environmental protection. Transparent portion 43a of encapsulating layer 43 is disposed over at least a portion of active area 41a. In certain embodiments, encapsulating layer 43 is disposed substantially over the entire top surface of the photovoltaic receiver 40.

The encapsulated cell circuit 49 also comprises prismatic cell cover 44 bonded to or molded into transparent portion 43a to refract focused sunlight away from electrically conductive gridlines 55, thereby improving cell current and power output.

The foregoing disclosure and description of the inventions are illustrative and explanatory. Various changes in the size, shape, and materials, as well as in the details of the illustrative construction and/or illustrative method may be made without departing from the spirit of the invention. For example, while the above illustrations and descriptions have been directed to include line-focus arched Fresnel lenses and silicon cells arranged in linear photovoltaic receivers in the focal lines of the arched lenses, the spirit of the invention applies equally to point-focus dome-shaped lenses and multi-junction cells arranged in a pattern corresponding to the focal spots of the dome lenses.

What is claimed is:

1. A photovoltaic receiver, comprising:
a. a photovoltaic cell comprising an active area, the active area further comprising an electrically conductive gridline;
b. an encapsulating layer disposed substantially about a predetermined portion of the photovoltaic cell, the encapsulating layer comprising a transparent portion disposed over a predetermined portion of the photovoltaic cell active area, the transparent portion further comprising a prismatic cell cover receiving surface area; and
c. a prismatic cell cover disposed on the prismatic cell cover receiving surface area of the transparent portion, the prismatic cell cover dimensioned and configured to refract focused sunlight away from the electrically conductive gridline on the solar cell.

2. The photovoltaic receiver of claim 1, wherein the encapsulating layer is dimensioned and configured to provide electrical isolation and environmental protection for the photovoltaic cell.

3. The photovoltaic receiver of claim 1, wherein the encapsulating layer is disposed substantially about the entire photovoltaic cell active area.

4. The photovoltaic receiver of claim 1, wherein the prismatic cell cover is at least one of bonded to or molded into the prismatic cell cover receiving surface area of the transparent portion.

5. The photovoltaic receiver of claim 1, wherein the photovoltaic cell is a concentrator cell dimensioned and configured for use in a focal line or focal spot of an optical concentrator.

6. The photovoltaic receiver of claim 1 wherein the prismatic cell cover comprises the same material as the transparent encapsulating layer.

7. The photovoltaic receiver of claim 6 wherein both the encapsulating layer and the prismatic cell cover comprise a transparent silicone material.

8. The photovoltaic receiver of claim 7 wherein the encapsulating layer and the prismatic cell cover comprise Dow Corning Sylgard® 184 or equivalent material.

9. The photovoltaic receiver of claim 1 wherein:
a. the electrically conductive gridline comprises multiple parallel gridlines dimensioned and configured with a fixed spacing between the multiple parallel gridlines; and
b. the prismatic cell cover comprises multiple partially cylindrically shaped optical elements comprising the same width as the spacing between gridlines;
c. wherein peaks of the partially cylindrical optical elements are located around halfway between gridlines.

10. The photovoltaic receiver of claim 1 wherein the prismatic cell cover is a discrete part relative to the transparent encapsulating layer.

11. The photovoltaic receiver of claim 1 wherein the prismatic cell cover is an integral part of the transparent encapsulating layer.

12. A photovoltaic receiver adapted for use as part of a concentrating photovoltaic module, comprising:
a. a carrier;
b. a first thermally loaded adhesive layer disposed on the carrier;
c. a dielectric layer disposed on the first thermally loaded adhesive layer;
d. a second thermally loaded adhesive layer disposed on the dielectric layer;
e. a solar cell assembly disposed on the second thermally loaded adhesive layer, the solar cell assembly further comprising a photovoltaic cell, the photovoltaic cell comprising an active area, the active area further comprising an electrically conductive gridline;
f. an encapsulating layer disposed substantially on a predetermined portion of the photovoltaic cell, the encapsulating layer comprising:
i. a transparent portion disposed over a predetermined portion of the photovoltaic cell active area; and
ii. a prismatic cell cover receiving surface area; and
g. a prismatic cell cover disposed on prismatic cell cover receiving surface area of the transparent portion, the prismatic cell cover dimensioned and configured to refract focused sunlight away from the electrically conductive gridline on the solar cell.

13. The photovoltaic receiver of claim 12, wherein the carrier comprises a metal.

14. The photovoltaic receiver of claim 12, wherein the first thermally loaded adhesive layer and the second thermally loaded adhesive layer comprise alumina-loaded silicone.

15. The photovoltaic receiver of claim 12, wherein the dielectric layer further comprises a plurality of redundant polyimide film layers bonded together.

16. The photovoltaic receiver of claim 15, wherein the redundant polyimide film layers are around 50μ thick.

17. The photovoltaic receiver of claim 15, wherein the redundant polyimide film layers comprise Kapton® CR® laminated with a layer of Teflon® FEP®.

18. The photovoltaic receiver of claim 12, wherein the solar cell assembly further comprises a bypass diode and a conductor, each operatively in electrical communication with the photovoltaic cell.

19. The photovoltaic receiver of claim 18, wherein the conductor comprises a solder plated copper ribbon.

20. The photovoltaic receiver of claim 12, wherein the encapsulating layer is dimensioned and configured to provide electrical isolation and environmental protection for the photovoltaic cell.

21. The photovoltaic receiver of claim 12, wherein the encapsulating layer is disposed substantially about the entire photovoltaic cell active area.

22. The photovoltaic receiver of claim 12, wherein the prismatic cell cover is at least one of bonded to or molded into the transparent portion.

23. The photovoltaic receiver of claim 12, wherein:
a, the solar cell assembly comprises multiple solar cells operatively interconnected in series electrically; and
b. the multiple layers including the carrier, thermally loaded adhesive layers, dielectric layer, and encapsulating layer are dimensioned and configured to enclose, protect, and insulate all of the multiple solar cells,

24. A photovoltaic concentrator, comprising:
a. a primary optical concentrator configured to collect and focus sunlight onto a photovoltaic receiver assembly, the photovoltaic receiver assembly further comprising:
i. a photovoltaic cell comprising an active area, the active area further comprising an electrically conductive gridline;
ii. an encapsulating layer disposed substantially on a predetermined portion of the photovoltaic cell, the encapsulating layer comprising a transparent portion disposed over a predetermined portion of the photovoltaic cell active area and a prismatic cell cover receiving surface area; and
iii. a prismatic cell cover disposed on the prismatic cell cover receiving surface area of the transparent portion, the prismatic cell cover further dimensioned and configured to refract focused sunlight away from the electrically conductive gridline on the photovoltaic cell.

25. The photovoltaic concentrator of claim 24, wherein the primary optical concentrator comprises a Fresnel lens.

26. The photovoltaic concentrator of claim 25, wherein the Fresnel lens is dimensioned and configured to focus incident sunlight into a focal line.

27. The photovoltaic concentrator of claim 25, wherein the Fresnel lens is configured to focus incident sunlight into a focal spot.
